(19) United States
(12) Patent Application Publication
(10) Pub. No.: US 2013/0181717 A1
(43) Pub. Date: Jul. 18, 2013

(54) POWER SUPPLY CIRCUIT AND MAGNETIC RESONANCE IMAGING APPARATUS

(71) Applicants: KABUSHIKI KAISHA TOSHIBA, Tokyo (JP); TOSHIBA MEDICAL SYSTEMS CORPORATION, Otawara-Shi (JP)

(72) Inventor: Motohiro MIURA, Yaita-Shi (JP)

(73) Assignees: TOSHIBA MEDICAL SYSTEMS CORPORATION, Otawara-Shi (JP); KABUSHIKI KAISHA TOSHIBA, Tokyo (JP)

(21) Appl. No.: 13/740,493

(22) Filed: Jan. 14, 2013

(30) Foreign Application Priority Data
Jan. 13, 2012 (JP) 2012-004693
Dec. 11, 2012 (JP) 2012-270216

(51) Int. Cl. H02M 7/04; G01R 33/28

(52) U.S. Cl. CPC H02M 7/04; G01R 33/28
USPC 324/322; 363/84

(57) ABSTRACT

According to one embodiment, a power supply circuit includes at least an input phase determining unit and an input phase switching unit. The input phase determining unit is configured to determine, of three phases of the input three-phase alternating current, a phase of a highest voltage and a phase of a lowest voltage at a given time. The input phase switching unit is configured to switch an input voltage to a primary coil of a transformer so as to input, during a first switching period, a voltage of the highest voltage phase to one terminal of the primary coil and a voltage of the lowest voltage phase to another terminal, and configured to input, during a second switching period being contiguous to the first switching period, a voltage of the lowest voltage phase to the one terminal and a voltage of the highest voltage phase to the another terminal.

### CROSS-REFERENCE TO RELATED APPLICATIONS

This application claims the benefit of priority of Japanese Patent Application No. 2012-004693, filed Jan. 13, 2012 and Japanese Patent Application No. 2012-270216, filed Dec. 11, 2012, the entire contents of all of which are incorporated herein by reference.

### FIELD

Embodiments described herein relate generally to a power supply circuit and a magnetic resonance imaging apparatus.

### BACKGROUND

Among devices that require direct current power, there are those that utilize power supply circuits such as a switched-mode power supply for converting commercial alternating current power into direct current power. For example, power supplies for gradient magnetic field (hereinafter referred to as gradient magnetic field power supplies) and receiving circuits of magnetic resonance imaging (MRI) apparatuses are driven with direct current power generated by switched-mode power supplies or the like being supplied thereto.

In general, with a switched-mode power supply, inputted alternating current power is rectified/smoothed to be given to a switching element, and a pulse wave generated by the switching element is inputted to a primary coil of a high-frequency transformer. Then, power induced at a secondary coil of the high-frequency transformer is rectified/smoothed, whereby predetermined direct current power is outputted.

An existing switched-mode power supply is configured to carry out rectification and smoothing at both of a primary-side circuit and a secondary-side circuit. Thus, in the existing switched-mode power, power losses occur at two rectifier circuits, respectively, and two relatively large capacitors are required at two locations, respectively, for smoothing twice.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is an overall configuration diagram showing an example of a magnetic resonance imaging apparatus that includes a power supply circuit according to a first embodiment of the present invention;

FIG. 2 is a block diagram schematically illustrating a configuration example of the power supply circuit according to the first embodiment;

FIG. 3 is a descriptive view showing an example of a voltage waveform of each phase to be outputted from the three-phase alternating current power supply;

FIG. 4 is a descriptive diagram showing an example of a voltage waveform to be outputted from the smoothing circuit;

FIG. 5 is a configuration diagram showing an example of the power supply circuit according to the first embodiment; and

FIG. 6 is a block diagram schematically illustrating a configuration example of a power supply circuit according to a second embodiment.

### DETAILED DESCRIPTION

Hereinbelow, a description will be given of a power supply circuit and a magnetic resonance imaging apparatus according to embodiments of the present invention with reference to the drawings.

In general, according to one embodiment, a power supply circuit is configured to convert an input three-phase alternating current into a direct current and output the direct current, and includes an input phase determining unit, a transformer, an input phase switching unit, a rectifying unit, and a smoothing unit.

The input phase determining unit is configured to determine, of three phases of the input three-phase alternating current, a phase that has a highest voltage and a phase that has a lowest voltage at a given time. The transformer has a primary coil and a secondary coil.

The input phase switching unit is configured to switch an input voltage to the primary coil so as to input, during a first switching period that is shorter than a cycle of the input three-phase alternating current, a voltage of the phase having the highest voltage to one terminal of the primary coil and a voltage of the phase having the lowest voltage to another terminal of the primary coil. And the input phase switching unit is configured to input, during a second switching period that is contiguous to the first switching period and is shorter than the cycle, a voltage of the phase having the lowest voltage to the one terminal and a voltage of the phase having the highest voltage to the another terminal.

The rectifying unit is connected to the secondary coil and configured to rectify an output voltage of the secondary coil. The smoothing unit is connected to the rectifying unit and configured to smooth an output voltage of the secondary coil to output the output voltage to an output terminal.

### First Embodiment

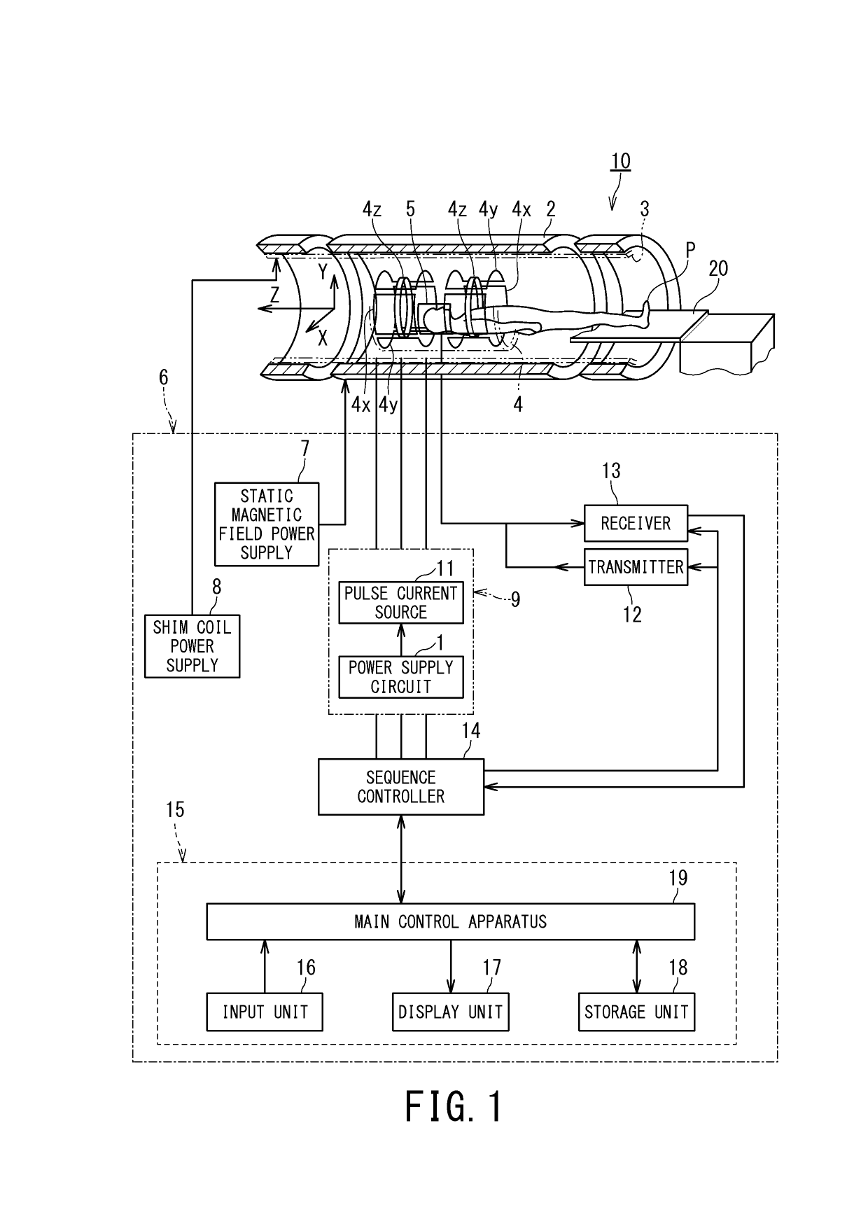

FIG. 1 is an overall configuration diagram showing an example of a magnetic resonance imaging apparatus 10 that includes a power supply circuit 1 according to a first embodiment of the present invention. FIG. 1 shows an example where the power supply circuit 1 is used as a direct current power supply in a gradient magnetic field power supply.

The magnetic resonance imaging apparatus 10 comprises a cylindrical static magnetic field magnet 2 for generating a static magnetic field, a shim coil 3 provided inside the static magnetic field magnet 2, a gradient magnetic field coil unit 4, and an RF coil unit 5, which are housed in a gantry.

The magnetic resonance imaging apparatus 10 further includes a control system 6. The control system 6 includes a power supply for static magnetic field (hereinafter referred to as static magnetic field power supply) 7, a shim coil power supply 8, a gradient magnetic field power supply 9 that includes the power supply circuit 1 and a pulse current source 11, a transmitter 12, a receiver 13, a sequence controller 14, and an information processing apparatus 15.

The information processing apparatus 15 includes an input unit 16, a display unit 17, a storage unit 18, and a main control apparatus 19.

The static magnetic field magnet 2 is connected to the static magnetic field power supply 7 and forms a static magnetic field in an imaging region with a current that is supplied from the static magnetic field power supply 7. The static magnetic field magnet 2 comprises a superconductive coil and is connected to the static magnetic field power supply 7 to be supplied with a current therefrom at the time of excitation. The static magnetic field magnet 2 may, however, be disconnected from the static magnetic field power supply 7 after once having been excited. Note that the static magnetic field magnet 2 may comprise a permanent magnet, and in this case, the static magnetic field power supply 7 does not need to be provided.

The cylindrical shim coil 3 is provided coaxially inside the static magnetic field magnet 2. The shim coil 3 is connected to the shim coil power supply 8, and a current is supplied to the shim coil 3 from the shim coil power supply 8 such that the static magnetic field becomes homogeneous.

The gradient magnetic field coil unit 4 includes an X-axis gradient magnetic field coil 4x, a Y-axis gradient magnetic field coil 4y, and a Z-axis gradient magnetic field coil 4z and is formed into a cylinder inside the static magnetic field magnet 2. A tabletop 20 is provided inside the gradient magnetic field coil unit 4 to serve as the imaging region, and an object P is placed on the tabletop 20. The RF coil unit 5 does not need to be housed in the gantry and may be provided in the vicinity of the tabletop 20 or the object P.

The X-axis gradient magnetic field coil 4x, the Y-axis gradient magnetic field coil 4y, and the Z-axis gradient magnetic field coil 4z of the gradient magnetic field coil unit 4 form, in the imaging region, a gradient magnetic field Gx in an X-axis direction, a gradient magnetic field Gy in a Y-axis direction, and a gradient magnetic field Gz in a Z-axis direction, respectively, with currents supplied from the gradient magnetic field power supply 9 that is controlled by the sequence controller 14. A slicing plane with respect to the object P can be set in accordance with how these gradient magnetic fields are applied.

Note that the gradient magnetic field power supply 9 may include 3 pairs of the power supply circuit 1 and the pulse current source 11 and apply a current individually to each of the gradient magnetic field coils 4x, 4y, and 4z to which the respective pairs of the power supply circuit 1 and the pulse current source 11 correspond.

The RF coil unit 5 is connected to the transmitter 12 and the receiver 13. The RF coil unit 5 has a function of transmitting to the object P a high-frequency signal received from the transmitter 12 and a function of providing to the receiver 13 a received MR signal generated with excitation by a high-frequency signal of nuclear spin inside the object P.

The sequence controller 14 of the control system 6 is connected to the gradient magnetic field power supply 9, the transmitter 12, and the receiver 13. The sequence controller 14 comprises a CPU and a storage medium such as a RAM and a ROM and stores sequence information that is received from the information processing apparatus 15. The sequence information includes control information that is necessary to drive the gradient magnetic field power supply 9, the transmitter 12, and the receiver 13. Such control information includes, for example, operation control information such as intensity, duration, and timing of a pulse current to be applied to the gradient magnetic field coil unit 4.

The sequence controller 14 controls the operation of the gradient magnetic field power supply 9, the transmitter 12, and the receiver 13 in accordance with this sequence information, to thereby generate, for example, the X-axis gradient magnetic field Gx, the Y-axis gradient magnetic field Gy, the Z-axis gradient magnetic field Gz, and a high-frequency signal. The transmitter 12 provides the high-frequency signal to the RF coil unit 5 in accordance with the control information received from the sequence controller 14. Further, digital data outputted from the receiver 13 (an MR signal) is provided to the information processing apparatus 15 through the sequence controller 14.

The input unit 16 of the information processing apparatus 15 comprises a typical input device such as a keyboard, a touch panel, a numeric keypad, and a trackball and outputs to the main control apparatus 19 an operation input signal corresponding to the operation by a user.

The display unit 17 comprises a typical display output device such as a liquid crystal display and an OLED (Organic Light Emitting Diode) display and displays various pieces of information such as a scanned image that is generated by the main control apparatus 19 in accordance with the control of the main control apparatus 19.

The storage unit 18 comprises a non-volatile storage medium on which the main control apparatus 19 can read and write data and stores various pieces of sequence information, raw image data, and various images such as scanned images.

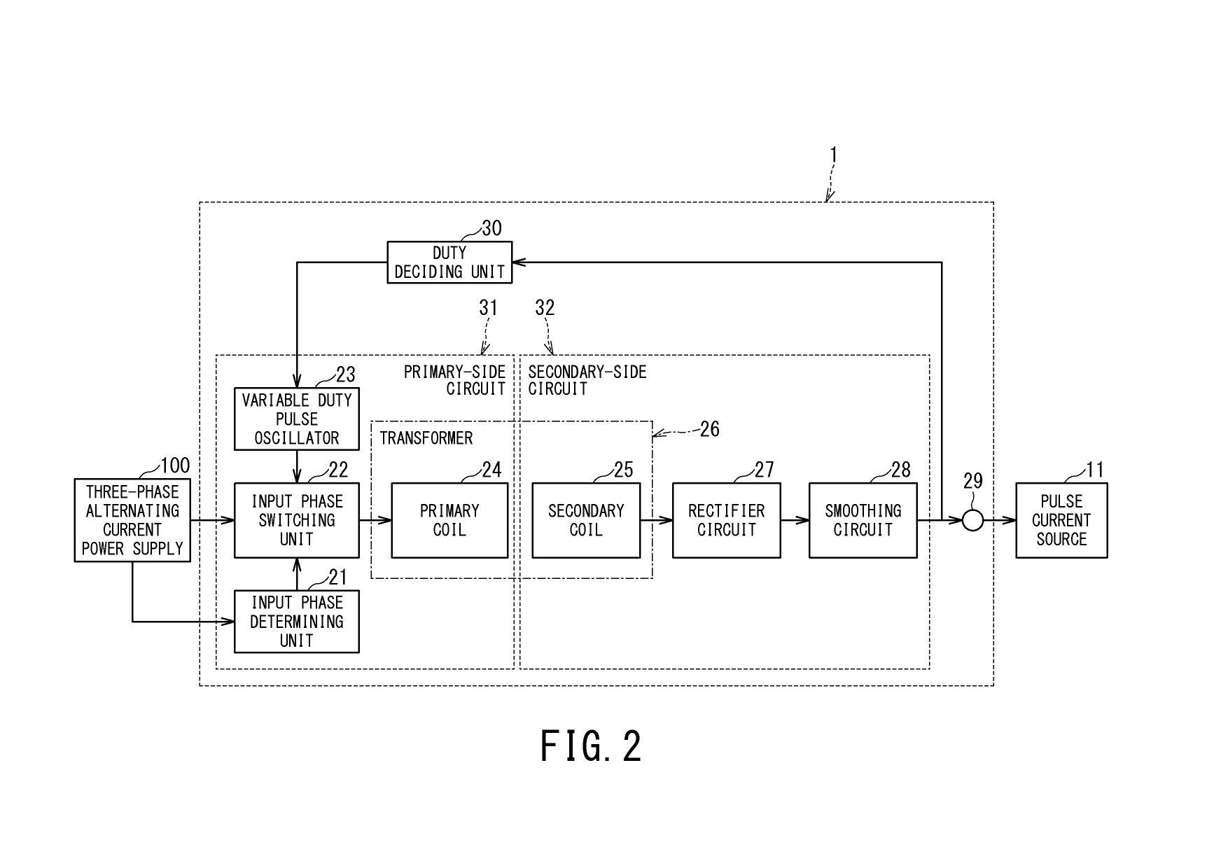

FIG. 2 is a block diagram schematically illustrating a configuration example of the power supply circuit 1 according to the first embodiment.

The power supply circuit 1 includes an input phase determining unit 21, an input phase switching unit 22, a variable duty pulse oscillator 23, a transformer 26 that has a primary coil 24 and a secondary coil 25, a rectifier circuit 27, a smoothing circuit 28, an output terminal 29, and a duty deciding unit 30.

A primary-side circuit 31 includes the input phase determining unit 21, the input phase switching unit 22, the variable duty pulse oscillator 23, and the primary coil 24 of the transformer 26. That is, the primary-side circuit 31 does not include a rectifier circuit and a smoothing circuit. In other words, the primary-side circuit 31 is consisted of a non-rectifying unit and a non-smoothing unit, and the non-rectifying unit and the non-smoothing unit are configured at least of the input phase determining unit 21 and the input phase switching unit 22. Meanwhile, a secondary-side circuit 32 includes the secondary coil 25 of the transformer 26, the rectifier circuit 27, and the smoothing circuit 28.

The input phase determining unit 21 is configured to be inputted with a three-phase alternating current from a three-phase alternating current power supply 100. The input phase determining unit 21 then determine, of the three phases, a phase that has a highest voltage and a phase that has a lowest voltage at a given time.

Note that a polyphase alternating current (e.g., two-phase, twelve-phase, twenty-four-phase) other than a three-phase alternating current may be inputted to the input phase determining unit 21. Even in a case where a polyphase alternating current other than a three-phase alternating current is inputted, the input phase determining unit 21 is configured to determine, of the inputted polyphase alternating current, a phase that has a highest voltage (hereinafter, referred to as a highest phase) and a phase that has a lowest voltage (hereinafter, referred to as a lowest phase) at a given time. In the description to follow, a case where a sinusoidal symmetrical three-phase alternating current is inputted to the input phase determining unit 21 will be illustrated as an example. Further, in the description to follow, phases of the sinusoidal symmetrical three-phase alternative current to be outputted from the three-phase alternating current power supply 100 are referred to as an R-phase, an S-phase, and a T-phase, respectively.

FIG. 3 is a descriptive view showing an example of a voltage waveform of each phase to be outputted from the three-phase alternating current power supply 100.

As shown in FIG. 3, the phases of the three-phase alternating current are in synchronization with one another but are out of phase with one another. Thus, a highest phase and a lowest phase sequentially change as time elapses. For example, within a period P1 of FIG. 3, the highest phase is the R-phase and the lowest phase is the T-phase. However, within a period P2, the highest phase is the R-phase and the lowest phase is the S-phase. Note that in the sinusoidal symmetrical three-phase alternating current, a voltage value of the highest phase is positive and a voltage value of the lowest phase is negative.

The input phase switching unit 22 is configured to receive information on the highest phase and the lowest phase from the input phase determining unit 21. Then, the input phase switching unit 22 is configured to switch input voltages to the primary coil 24 as follows. That is, the input phase switching unit 22 is configured to set, during a first switching period t1 that is shorter than a cycle of the input three-phase alternating current, an input voltage to one terminal of the primary coil 24 to a voltage of the highest phase and an input voltage of another terminal of the primary coil 24 to a voltage of the lowest phase. Further, the input phase switching unit 22 is configured to set, during a second switching period t2 that is contiguous to the first switching period t1 and is shorter than a cycle of the input three-phase alternating current, an input voltage to the one terminal to a voltage of the lowest phase and an input voltage to the another terminal to a voltage of the highest phase.

For example, upon receiving information indicating that the highest phase is the R-phase and the lowest phase is the T-phase within the period P1 shown in FIG. 3, the input phase switching unit 22 is configured to input the R-phase to one terminal of the primary coil 24 and the T-phase to another terminal thereof, respectively, during the first switching period t1. That is, the primary coil 24 is inputted with a voltage in which a voltage of the T-phase is subtracted from a voltage of the R-phase. Subsequently, the input phase switching unit 22 is configured to switch the input phases such that these inputs are inverted and input the T-phase to the one terminal and the R-phase to the another terminal during the second switching period t2. That is, the primary coil 24 is inputted with a voltage in which a voltage of the R-phase is subtracted from a voltage of the T-phase. Thereafter, the input phase switching unit 22 is configured to again input the R-phase to the one terminal of the primary coil 24 and the T-phase to the another terminal thereof during the first switching period t1. Then, upon transitioning into the period P2 after the period t1, the input phase switching unit 22 is configured to input the R-phase and the S-phase to the primary coil 24 such that the R-phase and the S-phase are inverted with each other.

Accordingly, the primary coil 24 is inputted with a voltage between a highest phase and a lowest phase at a given time of the input three-phase alternating current in pulses of a cycle t1+t2.

The variable duty pulse oscillator 23 is configured to set the first switching period t1 and the second switching period t2. The first switching period t1 and the second switching period t2 may be the same in duration with each other. Further, it is preferable that each of the switching periods t1 and t2 is sufficiently shorter than a cycle of the input three-phase alternating current (e.g., equal to or less than 1/10 thereof).

The secondary coil 25 of the transformer 26 outputs a voltage in accordance with a magnetic field that is generated with a pulse voltage inputted to the primary coil 24. Note that a direct current voltage value to be outputted from the output terminal 29 of the power supply circuit 1 can be varied in accordance with a ratio of the number of rounds of the primary coil 24 to that of the secondary coil 25.

The rectifier circuit 27 is connected to the secondary coil 25 and is configured to rectify an output signal of the secondary coil 25. The rectifier circuit 27 may comprise a typical circuit or device having a rectifying action such as a diode bridge.

The smoothing circuit 28 is connected to the rectifier circuit 27 and is configured to smooth an output signal of the secondary coil 25 to output to the output terminal 29 and the duty deciding unit 30. The smoothing circuit 28 may comprise a typical device or circuit having a smoothing action such as a capacitor.

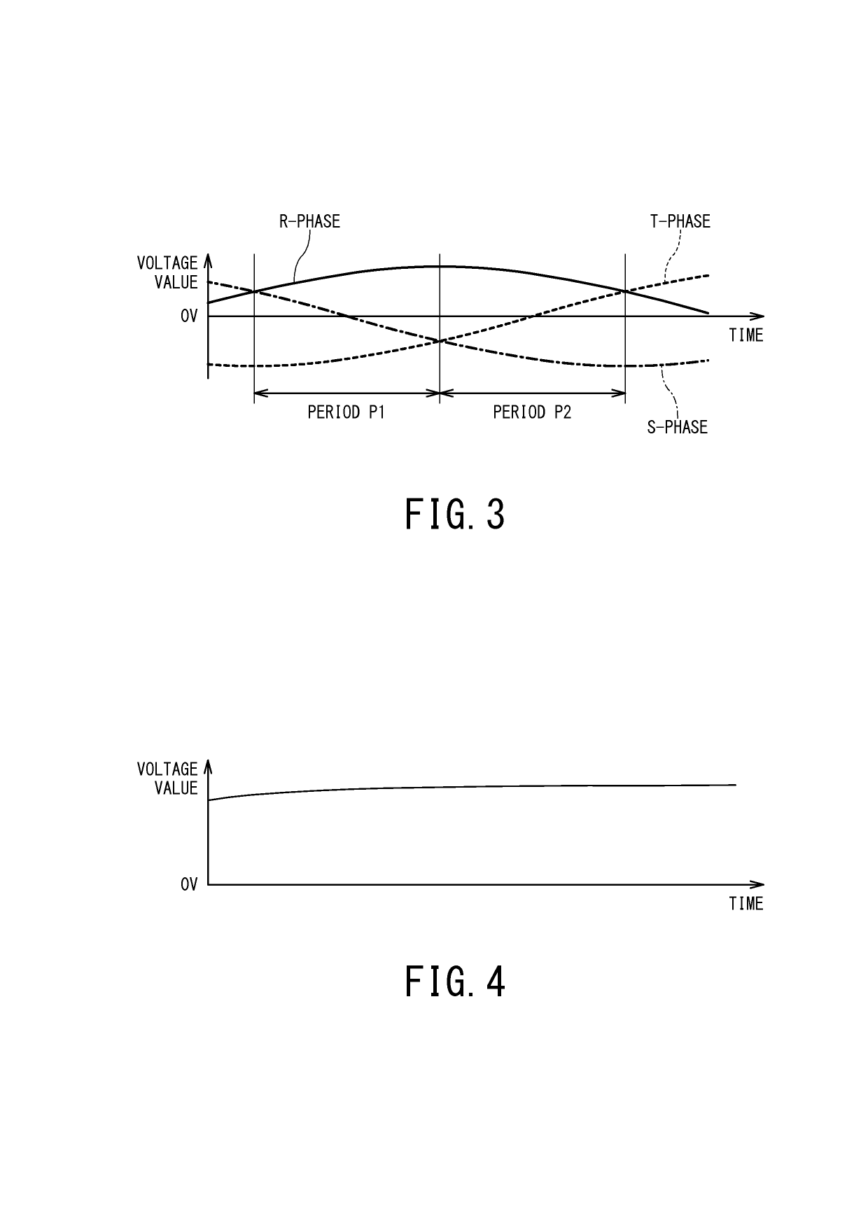

FIG. 4 is a descriptive diagram showing an example of a voltage waveform to be outputted from the smoothing circuit 28.

The output terminal 29 outputs a signal received from the smoothing circuit 28 to the pulse current source 11.

With the above-described circuit configuration, the smoothing circuit 28 can be configured to output a direct current voltage as shown in FIG. 4.

Accordingly, according to the power supply circuit 1 of the present embodiment, even when the primary-side circuit 31 does not include a rectifier circuit and a smoothing circuit (i.e., even when the primary-side circuit 31 is consisted of a non-rectifying portion and a non-smoothing portion), alternating current power can be converted into direct current power. Therefore, compared to a case where the primary-side circuit 31 includes a rectifier circuit and a smoothing circuit, the number of components can be reduced, and a power loss to be incurred in the rectifier circuit can be suppressed.

Further, the cycle t1+t2 of a voltage pulse to be inputted to the primary coil 24 can be controlled by the variable duty pulse oscillator 23 to be shorter than a cycle of the three-phase alternating current power supply 100. Thus, the transformer 26 can be reduced in size. In general, the size of the transformer 26 is known to be inversely proportional to the frequency thereof.

Here, according to the above-described circuit configuration, although the smoothing circuit 28 can be configured to output a direct current voltage, voltage changes of the R-phase and the T-phase appear as a variation in the direct current voltage to be outputted from the smoothing circuit 28 during, for example, the period t1.

In order to output a more stable direct current voltage, it is contemplated to control the first switching period t1 and the second switching period t2 using (or feeding back) an output voltage of the smoothing circuit 28.

Accordingly, the duty deciding unit 30 is configured to compare an output voltage of the smoothing circuit 28 with a target voltage (hereinafter, referred to as a reference voltage) and decide the first switching period t1 and the second switching period t2 such that the output voltage of the smoothing circuit 28 approaches the reference voltage.

To be more specific, when an output voltage of the smoothing circuit 28 is greater than the reference voltage, the duty deciding unit 30 carries out a control such that a ratio t1/t2, which is a ratio of the first switching period t1 to the second switching period t2, is reduced. The second switching period t2 is a period during which a voltage (a negative value) in which a voltage of the R-phase (a positive value) is subtracted from a voltage of a lowest phase (a negative value) is inputted to the primary coil 24. Thus, the output voltage of the smoothing circuit 28 can be reduced by reducing the ratio t1/t2. On the other hand, when an output voltage of the smoothing circuit 28 is lower than the reference voltage, a control is carried out to increase the ratio t1/t2.

Then, the duty deciding unit 30 is configured to provide the variable duty pulse oscillator 23 with the decided first switching period t1 and second switching period t2. The variable duty pulse oscillator 23 is configured to control the input phase switching unit 22 using the first switching period t1 and the second switching period t2 that are decided by the duty deciding unit 30.

Note that the duty deciding unit 30 may, for example, be configured to change the ratio t1/t2 only when an absolute value of a difference between an output voltage of the smoothing circuit 28 and the reference voltage is greater than a predetermined threshold and set t1/t2=1 when the aforementioned absolute value is within the threshold.

Using the duty deciding unit 30 makes it possible to stabilize a direct current voltage to be outputted from the output terminal 29. Thus, a ripple in an output voltage caused by a variation in the input three-phase alternating current can be reduced. Further, even in a case where, for example, a load connected to the output terminal 29 changes, a variation in the output voltage can be suppressed. The variable duty pulse oscillator 23 and the duty deciding unit 30 function as a period control unit configured to control the first switching period t1 and the second switching period t2.

Note that, when a direct current voltage to be outputted from the output terminal 29 does not need to be stabilized, the power supply circuit 1 does not need to include the duty deciding unit 30. In this case, the variable duty pulse oscillator 23 is configured to control the input phase switching unit 22 using the first switching period t1 and the second switching period t2 that are set in advance and the ratio t1/t2 (e.g., 1). For example, in a case where the power supply circuit 1 is used as a power supply for the pulse current source 11 in the gradient magnetic field power supply 9 as in the magnetic resonance imaging apparatus 10 according to the present embodiment, the control of the ratio t1/t2 by the duty deciding unit 30 is not necessary if the pulse current source 11 is provided with a feedback function or the like to allow a ripple to a certain degree.

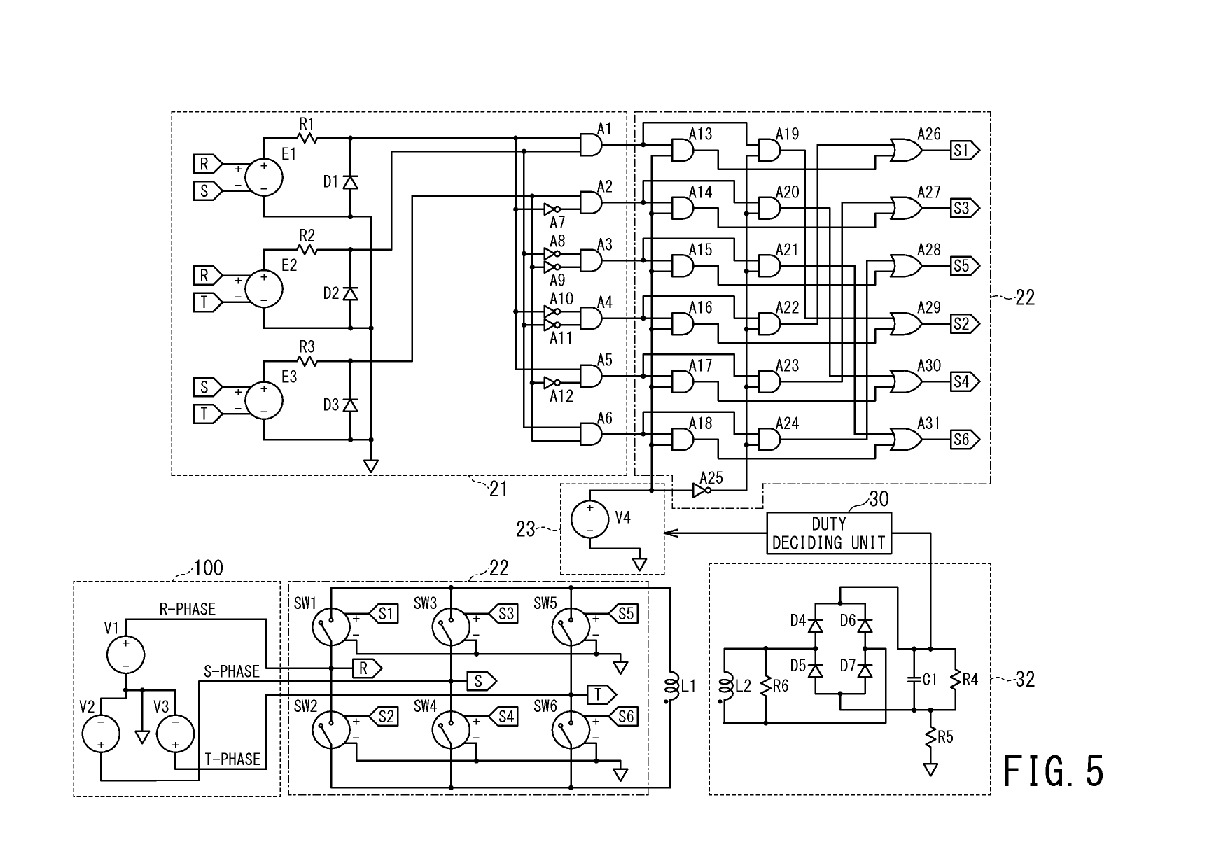

FIG. 5 is a configuration diagram showing an example of the power supply circuit 1 according to the first embodiment. Note that the input phase switching unit 22 is shown as being divided into two due to a limitation of space.

The power supply circuit 1 may comprise, for example, discrete components and logic circuits as shown in FIG. 5. In FIG. 5, a capacitor C1, diodes D1 to D7, resistors R1 to R6, a primary coil L1 serving as the primary coil 24, a secondary coil L2 serving as the secondary coil 25, switches SW1 to SW6, AND circuits A1 to A6 and A13 to A24, NOT circuits A7 to A12 and A25, and OR circuits A26 to A31 are shown. In the description to follow, one terminal of the primary coil 24 (L1 in FIG. 5) is a terminal at an upper side in FIG. 5, and another terminal thereof is a terminal at a lower side in FIG. 5.

For example, an output of A1 in the input phase determining unit 21 shown in FIG. 5 is H only when the R-phase is the highest phase and is L in other cases. Further, an output of A4 is H only when the R-phase is the lowest phase and is L in other cases. Accordingly, using an output of the input phase determining unit 21 having the configuration shown in FIG. 5 makes it possible to extract a highest phase and a lowest phase at a given time.

Further, as is clear from FIG. 5, an output of A26 (S1 in FIG. 5) in the input phase switching unit 22 outputs H when the R-phase is the highest phase and an output of the variable duty pulse oscillator 23 is H or when the R-phase is the lowest phase and an output of the variable duty pulse oscillator 23 is L and outputs L in other cases. This output of A26 (S1 in FIG. 5) is inputted to the switch SW1.

The switches SW1, SW3, and SW5 of the input phase switching unit 22 are shorted to input voltages of the R-phase, the S-phase, and the T-phase to the one terminal (the terminal at the upper side in FIG. 5) of the primary coil 24 (L1 in FIG. 5) only when outputs of A26, A27, and A28, respectively, are H. The switches SW2, SW4, and SW6 are shorted to input voltages of the R-phase, the S-phase, and the T-phase to the another terminal (the terminal at the lower side in FIG. 5) of the primary coil 24 (L1 in FIG. 5) only when outputs of A29, A30, and A31, respectively, are H.

Thus, the switch SW1 is shorted to input a voltage of the R-phase to the one terminal of the primary coil 24 (L1 in FIG. 5) when the R-phase is the highest phase and an output of the variable duty pulse oscillator 23 is H or when the R-phase is the lowest phase and an output of the variable duty pulse oscillator 23 is L.

Further, an output of A31 (S6 in FIG. 5) in the input phase switching unit 22 outputs H when the T-phase is the lowest phase and an output of the variable duty pulse oscillator 23 is H or when the T-phase is the highest phase and an output of the variable duty pulse oscillator 23 is L and outputs L in other cases. This output of A31 (S6 in FIG. 5) is inputted to the switch SW6.

Accordingly, within, for example, the period P1 in which the highest phase is the R-phase and the lowest phase is the T-phase, during the first switching period t1 in which an output of the variable duty pulse oscillator 23 (V4 in FIG. 5) is H, the switches SW1 and SW6 are shorted, whereby the R-phase is inputted to the one terminal of the primary coil 24 and the T-phase is inputted to the another terminal thereof, respectively.

Similarly, an output of A29 (S2 in FIG. 5) in the input phase switching unit 22 outputs H when the R-phase is the lowest phase and an output of the variable duty pulse oscillator 23 is H or when the R-phase is the highest phase and an output of the variable duty pulse oscillator 23 is L and outputs L in other cases.

Further, an output of A28 (S5 in FIG. 5) in the input phase switching unit 22 outputs H when the T-phase is the highest phase and an output of the variable duty pulse oscillator 23 is H or when the T-phase is the lowest phase and an output of the variable duty pulse oscillator 23 is L and outputs L in other cases.

Accordingly, within, for example, the period P1 in which the highest phase is the R-phase and the lowest phase is the T-phase, during the second switching period t2 in which an output of the variable duty pulse oscillator 23 (V4 in FIG. 5) is L, the switches SW2 and SW5 are shorted, whereby the T-phase is inputted to the one terminal of the primary coil 24 and the R-phase is inputted to the another terminal thereof, respectively.

### Second Embodiment

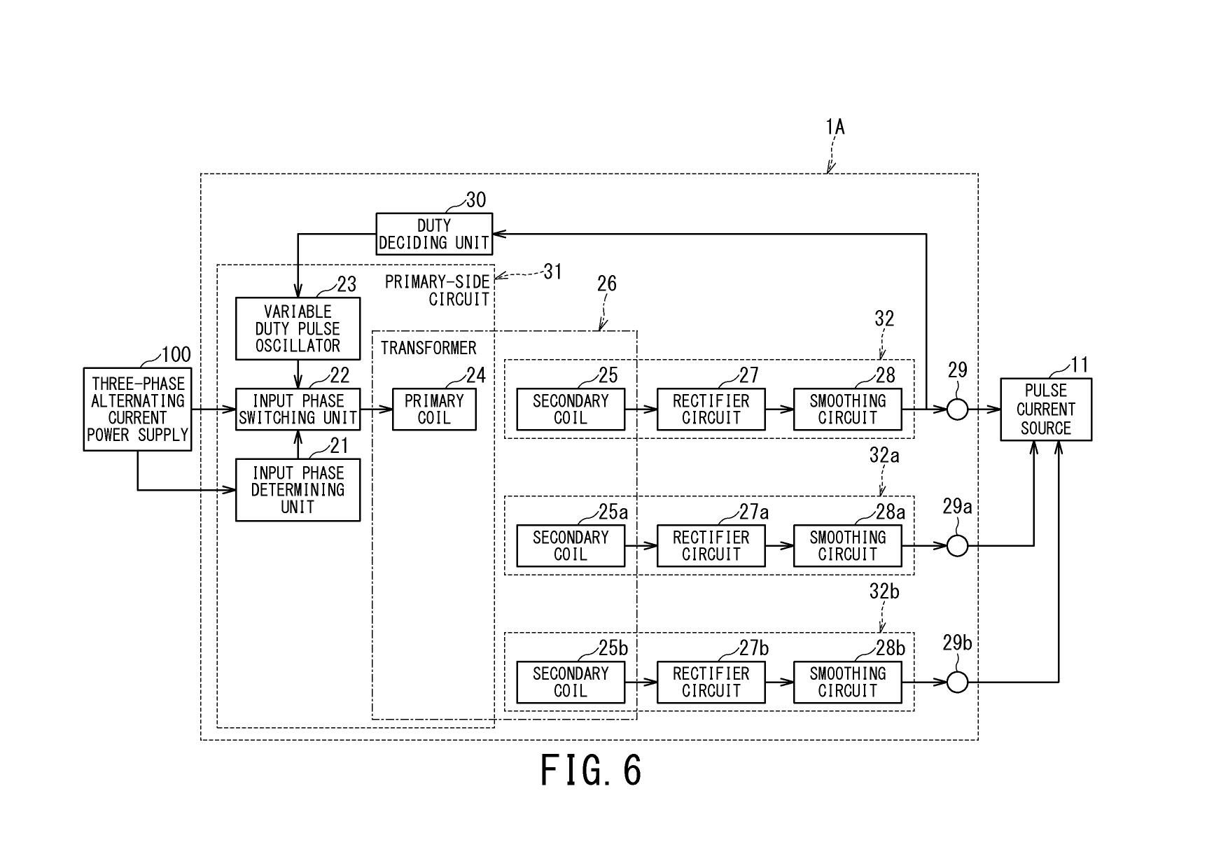

FIG. 6 is a block diagram schematically illustrating a configuration example of a power supply circuit 1A according to a second embodiment.

The power supply circuit 1A of the second embodiment differs from the power supply circuit 1 of the first embodiment in that the secondary-side circuit 32 that includes a combination of the secondary coil 25, the rectifier circuit 27, and the smoothing circuit 28 is provided in plurality. Since other configurations and actions do not substantially differ from those of the power supply circuit 1 shown in FIG. 2, the same reference characters are given to the same configurations, and the description thereof will be omitted. FIG. 6 illustrates an example where the power supply circuit 1A includes three secondary-side circuits 32, 32a, and 32b.

The secondary-side circuit 32a includes a secondary coil 25a, a rectifier circuit 27a, and a smoothing circuit 28a that is connected to an output terminal 29a. The secondary-side circuit 32b includes a secondary coil 25b, a rectifier circuit 27b, and a smoothing circuit 28b that is connected to an output terminal 29b.

The transformer 26 includes the primary coil 24 and the secondary coils 25, 25a, and 25b. Each of the secondary coils 25, 25a, and 25b is configured to be magnetically coupled to the primary coil 24.

Even with the power supply circuit 1A of the present embodiment, similar effects to those of the power supply circuit 1 of the first embodiment can be achieved.

Further, according to the power supply circuit 1A of the present embodiment, distinct voltages can be outputted from the respective output terminals 29, 29a, and 29b in accordance with a ratio of the number of rounds of the primary coil 24 to that of the secondary coils 25, 25a, and 25b.

Each of the output terminals 29, 29a, and 29b does not need to be grounded (e.g., in an exemplary circuit shown in FIG. 5, the resistor R5 and an earth to which the resistor R5 is to be connected may not be provided), and may be floating. In a case where each of the output terminals 29, 29a, and 29b is floating, each of the output voltages can be controlled independently. Further, in this case, the pulse current source 11 can, for example, connect the respective floating output voltages in series for utilization.

Further, the output terminals 29, 29a, and 29b can be connected in series and outputted in that state to an external device such as the pulse current source 11. At this time, any of the output terminals may be grounded.

The duty deciding unit 30 can be configured to stabilize each of the output voltages by using one of the output voltages. That is because any of the output voltages varies in accordance with a magnetic field generated by the primary coil 24.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the power supply circuit 1 can be applied not only to the magnetic resonance imaging apparatus 10 but also as a direct current power supply for various devices that utilize direct current power. Further, for example, in the second embodiment as well, similarly to the first embodiment, in a case where the direct current voltages to be outputted from the output terminals 29, 29a, and 29b do not need to be stabilized, the power supply circuit 1A does not need to include the duty deciding unit 30.

What is claimed is:

1. A power supply circuit configured to convert an input three-phase alternating current into a direct current and output the direct current, the power supply circuit comprising:
an input phase determining unit configured to determine, of three phases of the input three-phase alternating current, a phase that has a highest voltage and a phase that has a lowest voltage at a given time;
a transformer having a primary coil and a secondary coil;
an input phase switching unit configured to switch an input voltage to the primary coil so as to input, during a first switching period that is shorter than a cycle of the input three-phase alternating current, a voltage of the phase having the highest voltage to one terminal of the primary coil and a voltage of the phase having the lowest voltage to another terminal of the primary coil and to input, during a second switching period that is contiguous to the first switching period and is shorter than the cycle, a voltage of the phase having the lowest voltage to the one terminal and a voltage of the phase having the highest voltage to the another terminal;
a rectifying unit connected to the secondary coil and configured to rectify an output voltage of the secondary coil; and
a smoothing unit connected to the rectifying unit and configured to smooth an output voltage of the secondary coil to output the output voltage to an output terminal.

2. The power supply circuit according to claim 1, wherein the input phase determining unit and the input phase switching unit are consisting of a non-rectifying portion and a non-smoothing portion.

3. The power supply circuit according to claim 1, wherein the input phase switching unit includes a period control unit configured to control the first switching period and the second switching period.

4. The power supply circuit according to claim 3, wherein the period control unit is configured to compare an output voltage of the smoothing unit with a predetermined reference voltage and control the first switching period and the second switching period so as to make an output voltage of the smoothing unit approach the reference voltage.

5. The power supply circuit according to claim 1, further comprising a plurality of secondary-side circuits each including the secondary coil, the rectifying unit, and the smoothing unit.

6. The power supply circuit according to claim 5, wherein the plurality of secondary-side circuits are connected to respective distinct output terminals, and the respective distinct output terminals are not grounded.

7. A magnetic resonance imaging apparatus, comprising:
a static magnetic field power supply;
a static magnetic field magnet configured to be supplied with a current from the static magnetic field power supply to form a static magnetic field in an imaging region;
a gradient magnetic field power supply;
a gradient magnetic field coil configured to be supplied with a current from the gradient magnetic field power supply to form a gradient magnetic field in the imaging region; and
an RF coil configured to transmit a high-frequency signal to an object located in the imaging region and receives a magnetic resonance signal generated inside the object in response to the high-frequency signal,
wherein the gradient magnetic field power supply comprises
a power supply circuit configured to convert an input three-phase alternating current into a direct current and output the direct current; and
a pulse current source connected to an output terminal of the power supply circuit to supply a current to the gradient magnetic field coil,
the power supply circuit comprising
an input phase determining unit configured to determine, of three phases of the input three-phase alternating current, a phase that has a highest voltage and a phase that has a lowest voltage at a given time,
a transformer having a primary coil and a secondary coil,
an input phase switching unit configured to switch an input voltage to the primary coil so as to input, during a first switching period that is shorter than a cycle of the input three-phase alternating current, a voltage of the phase having the highest voltage to one terminal of the primary coil and a voltage of the phase having the lowest voltage to another terminal of the primary coil and to input, during a second switching period that is contiguous to the first switching period and is shorter than the cycle, a voltage of the phase having the lowest voltage to the one terminal and a voltage of the phase having the highest voltage to the another terminal,
a rectifying unit connected to the secondary coil and configured to rectify an output voltage of the secondary coil, and
a smoothing unit connected to the rectifying unit and configured to smooth an output voltage of the secondary coil to output the output voltage to the output terminal.
